(19) United States
(12) Patent Application Publication
(10) Pub. No.: US 2013/0277085 A1
(43) Pub. Date: Oct. 24, 2013

(54) Weatherproof While-in-Use Floor Cover

(71) Applicant: THOMAS & BETTS INTERNATIONAL, INC., Wilmington, DE (US)

(72) Inventors: Cong T. Dinh, Collierville, TN (US); Mark R. Drane, Germantown, TN (US); Peter J. Gallucci, Collierville, TN (US)

(73) Assignee: Thomas & Betts International, Inc., Wilmington, DE (US)

(21) Appl. No.: 13/759,337

(22) Filed: Feb. 5, 2013

Related U.S. Application Data
(60) Provisional application No. 61/636,166, filed on Apr. 20, 2012.

(51) Int. Cl. H05K 5/00

(52) U.S. Cl. CPC H05K 5/00
USPC 174/50

(57) ABSTRACT

A weatherproof while-in-use floor cover is provided for allowing access to a while-in-use box which is mounted below an elevated floor. The while-in-use floor cover comprises a frame and a lid and is constructed such that a cut-out exists along an edge of the lid to provide a passage for an electrical cord in order that the electrical cord may be plugged in to the while-in-use box which is mounted below the elevated floor when the lid of the while-in-use floor cover is in the closed position.

### CROSS-REFERENCE TO RELATED APPLICATION

This application claims priority under 35 U.S.C. § 119, based on U.S. Provisional Patent Application No. 61/636,166, filed Apr. 20, 2012, the disclosure of which is hereby incorporated by reference herein.

### FIELD OF THE INVENTION

In general, the present invention relates to a weatherproof while-in-use floor cover which creates an opening to provide access to while-in-use box and cover outlet which is mounted below the surface of an elevated floor.

### BACKGROUND

In residential construction, there are often circumstances where having an outlet mounted underneath an elevated flooring surface, particularly the flooring of a deck, would be beneficial for various outdoor applications which require electricity, such as an outdoor radio, lighting, electric cooking device, etc. However, to have easy access to a while-in-use box and cover outlet would require a device which can be opened and closed from the flooring surface, while allowing an electrical cord to be plugged in to the outlet which is underneath the flooring surface.

### SUMMARY OF THE INVENTION

The present invention provides a weatherproof while-in-use floor cover, particularly for, but not limited to, a deck. The weatherproof while-in-use floor cover opens and closes to allow easy access to a while-in-use box and cover for an electrical outlet which is mounted below the flooring surface so that an electrical cord can be plugged into the while-in-use box below the flooring surface and then used to power electrical devices which are above the flooring surface, even when the weatherproof while-in-use floor cover is in the closed position. The while-in-use floor cover may be sized to accommodate openings for single or multiple gang applications.

### BRIEF DESCRIPTION OF THE DRAWINGS

FIG. 1 is a bottom plan view of a weatherproof while-in-use floor cover of the present invention.

FIG. 2 is a front perspective view of a weatherproof while-in-use floor cover of the present invention.

FIG. 3 is an elevation view of a weatherproof while-in-use floor cover of the present invention with the while-in-use floor cover in the open position.

FIG. 4 is an elevation view of a weatherproof while-in-use floor cover of the present invention with the while-in-use floor cover in the closed position.

FIG. 5 is a top plan view of a weatherproof while-in-use floor cover of the present invention with the while-in-use floor cover in the closed position.

FIG. 6 is a top plan view of a weatherproof while-in-use floor cover of the present invention with the while-in-use floor cover in the open position.

FIG. 7 is a front perspective view of a simple hinge of the weatherproof while-in-use floor cover of the present invention.

FIG. 8 is a front perspective view of a weatherproof while-in-use floor cover of the present invention with a circular shaped lid and frame.

FIG. 9 is a front perspective view of a weatherproof while-in-use floor cover of the present invention with an oval shaped lid and frame.

### DETAILED DESCRIPTION OF THE PREFERRED EMBODIMENT(S)

The above and other features, aspects and advantages of the present invention will now be discussed in the following detailed description of preferred embodiments and appended claims, which are to be considered in conjunction with the accompanying drawings in which identical reference characters designate like elements throughout the views.

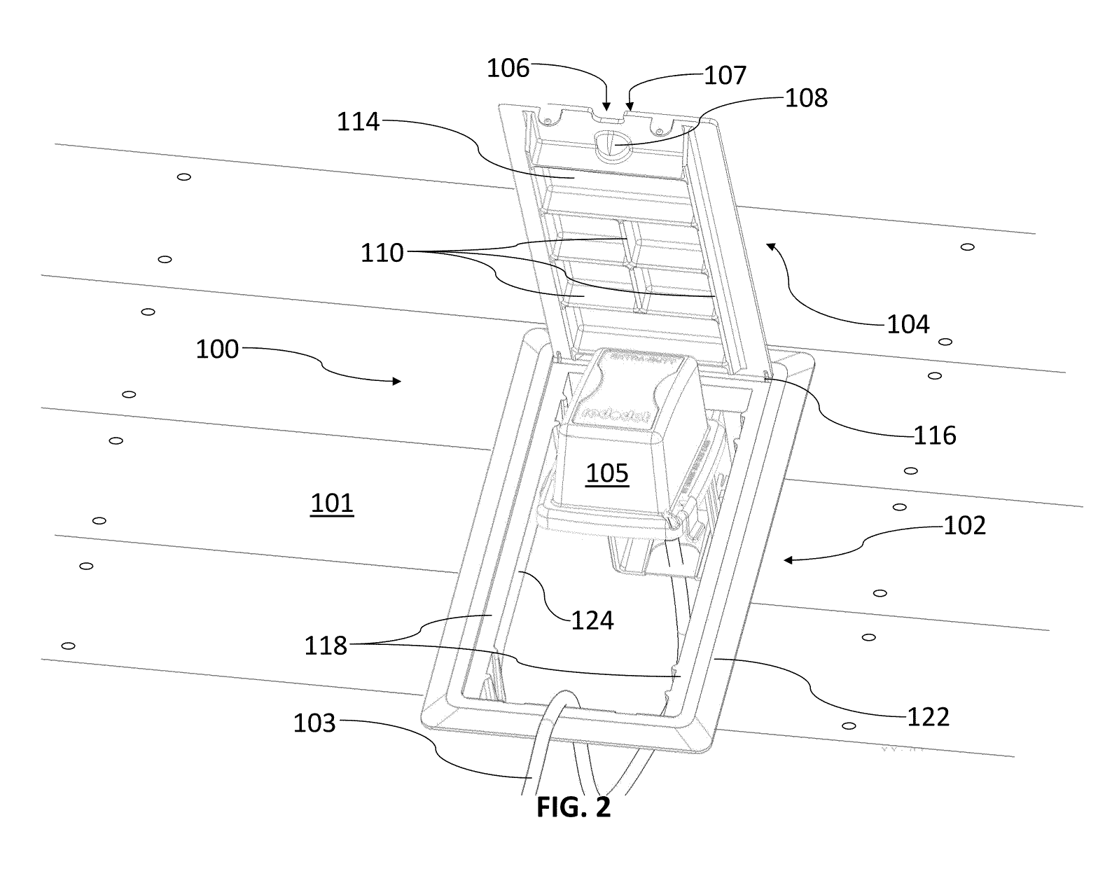

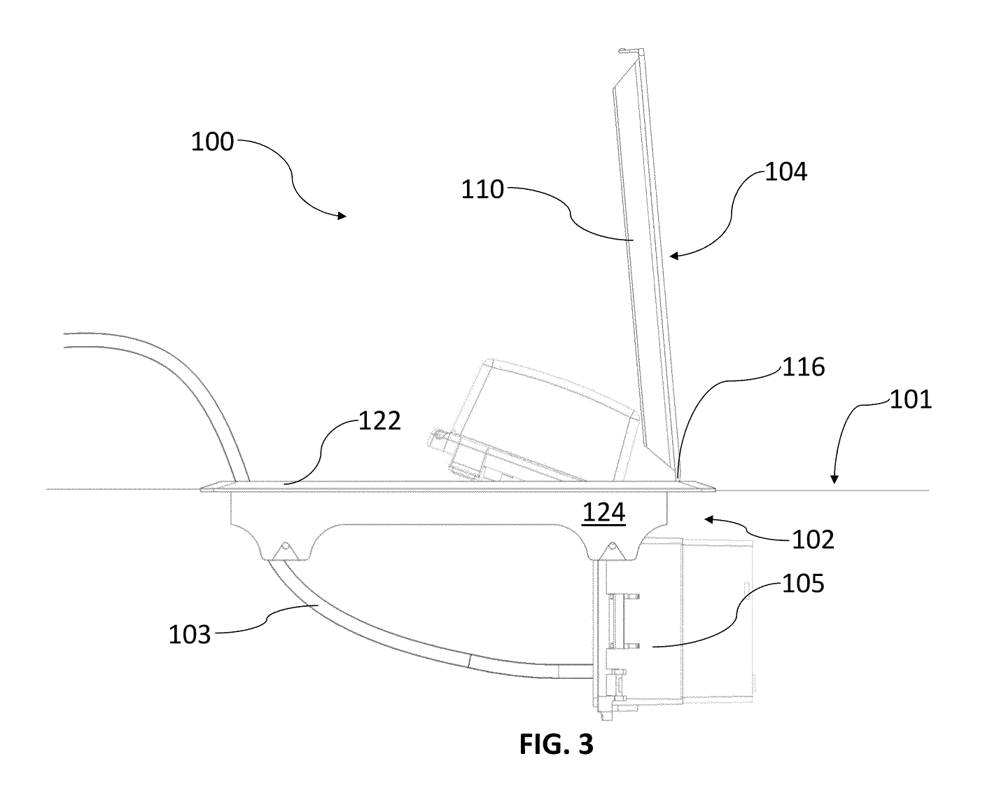

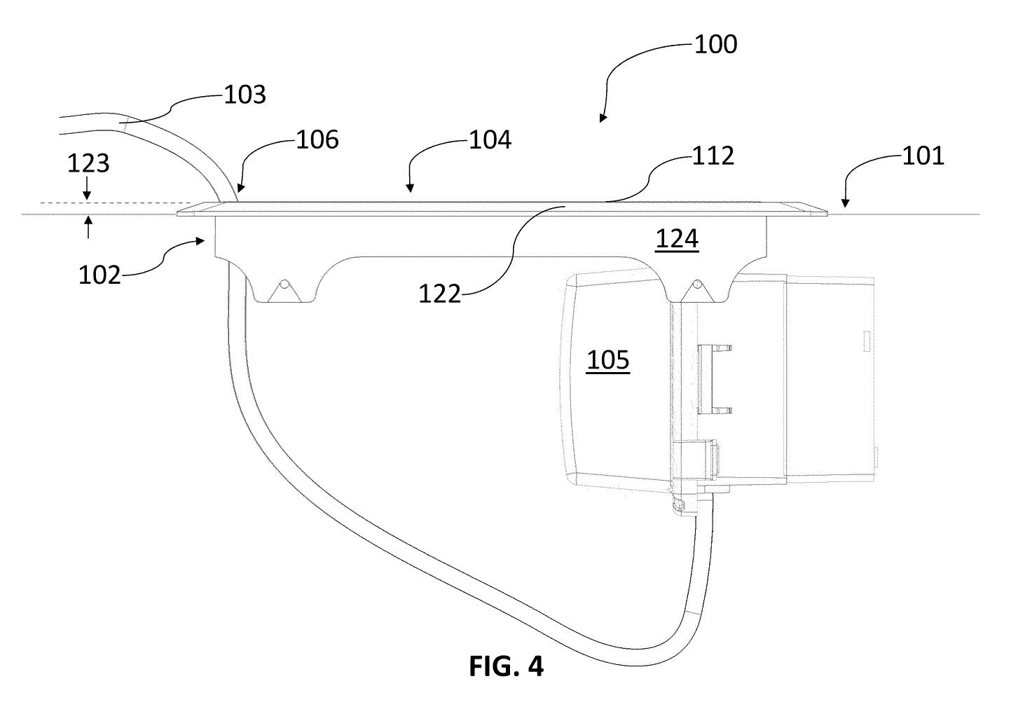

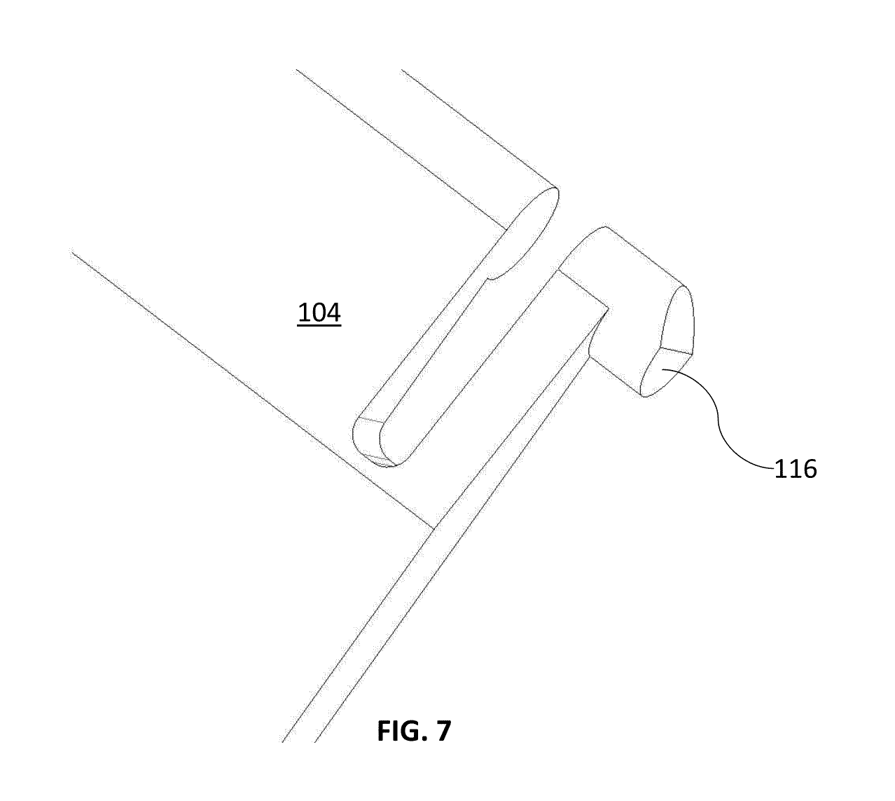

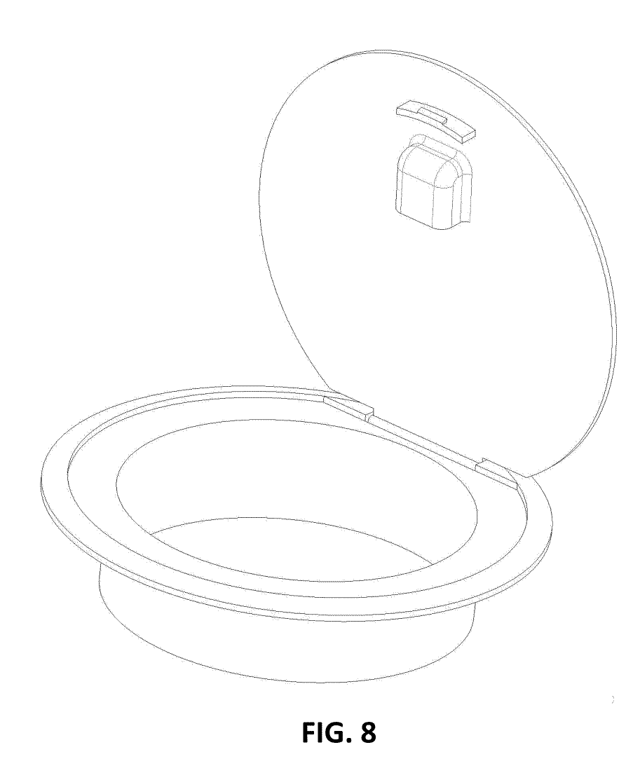

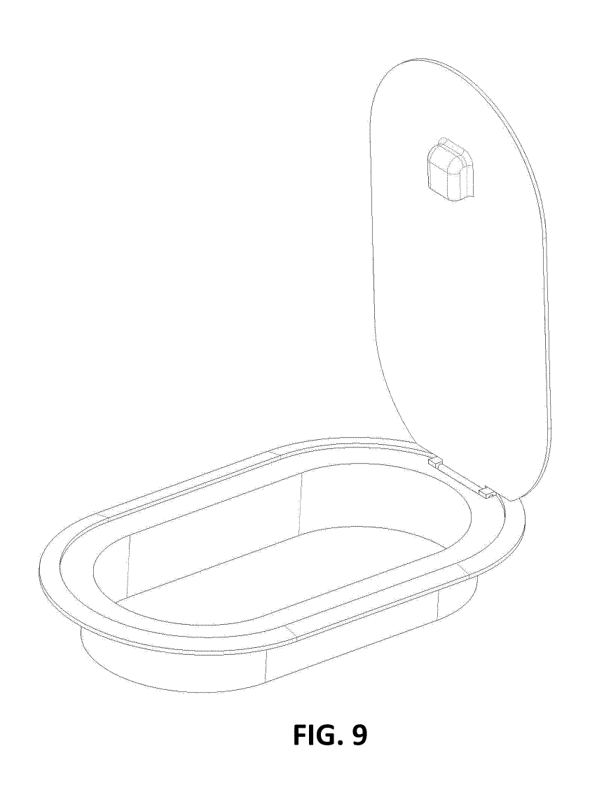

In FIG. 2 a front perspective view is shown of the present invention of a weatherproof while-in-use floor cover 100, which may be constructed of metal or plastic materials. In this figure, the floor cover is shown in the open position. The while-in-use floor cover 100 comprises a rectangular shape frame 102 and a rectangular shape lid 104. Although in this figure the shape of the frame and lid is rectangular, it is understood that the frame and lid may be another shape, such as circular or oval, as is shown in FIGS. 8 and 9. The lid 104 is attached to the frame 102 by a simple hinge 116, such as a flush hinge or a pin hinge, as shown in FIG. 7, which allows the lid to be opened and closed by an operator. The hinge 116 does not allow the lid 104 of the while-in-use floor cover 100 to be opened beyond 90 degrees from the closed position. This limitation on the angle of opening causes the lid to close due to the force of gravity, which pulls the lid back to the closed position if the lid is not being actively held open by an operator. This feature ensures that the lid 104 of the while-in-use floor cover 100 is never left in the open position. The while-in-use floor cover 100 is shown mounted within an opening in the floor of a deck 101. Though the type of flooring shown in FIG. 2 is a deck, it is understood that the while-in-use floor cover 100 could be mounted within an opening of any type of elevated floor. The while-in-use floor cover 100 is secured in position within the opening in the floor by at least one frame mounting wall 124, which is more clearly shown in FIGS. 3 and 4, which protrudes perpendicularly downward from at least one side of the frame 102. The frame mounting wall 124 can then be affixed to the flooring of the deck 101 by screws or nails.

The opening in which the while-in-use floor cover 100 is mounted is located directly above a while-in-use box and cover 105 for an outlet, which is mounted under the flooring of the deck 101. It is understood that the while-in-use floor cover may be sized to accommodate openings for single or multiple gang applications. When the lid 104 is opened by an operator, the while-in-use box and cover 105 which is located below the while-in-use floor cover 100 is revealed. The lid 104 is designed to not open beyond 90 degrees so that it will close by force of gravity if left open by an operator, thus preventing an exposed opening in the floor of the deck that could be a hazard to persons walking on the deck. With the lid 104 in the open position, an electrical cord 103 which is connected to an electrical device can be plugged in to the outlet which is housed by the while-in-use box and cover 105 that is located under the flooring of the deck 101, as is shown in FIG. 2.

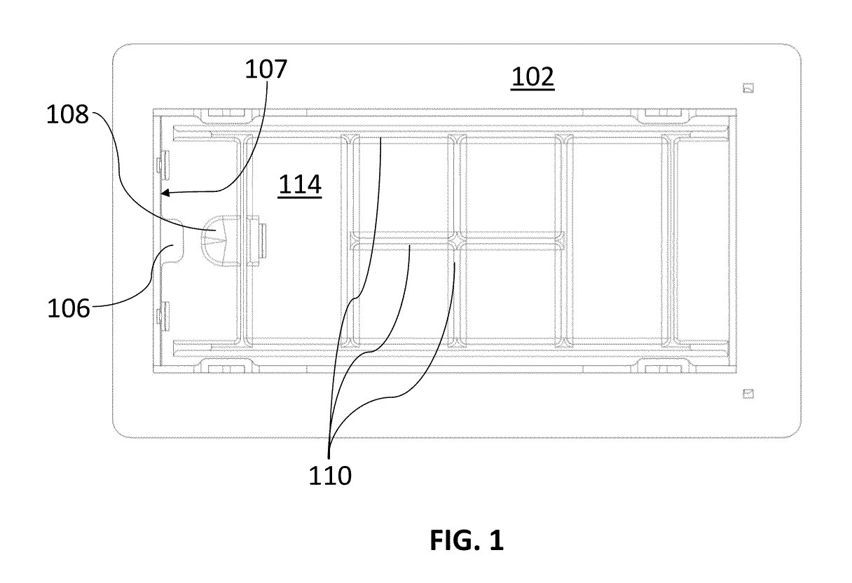

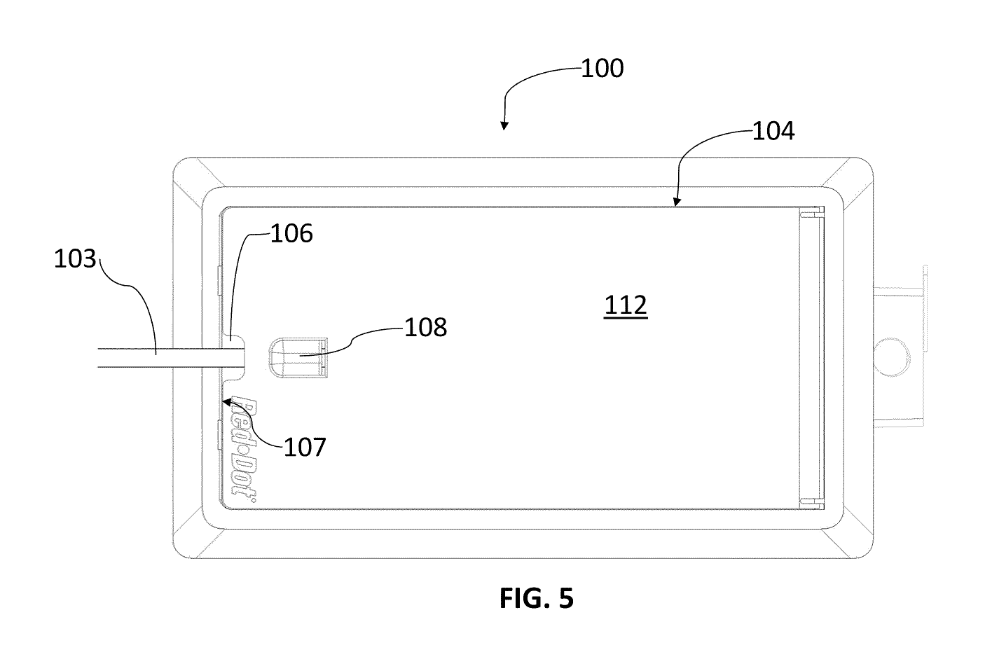

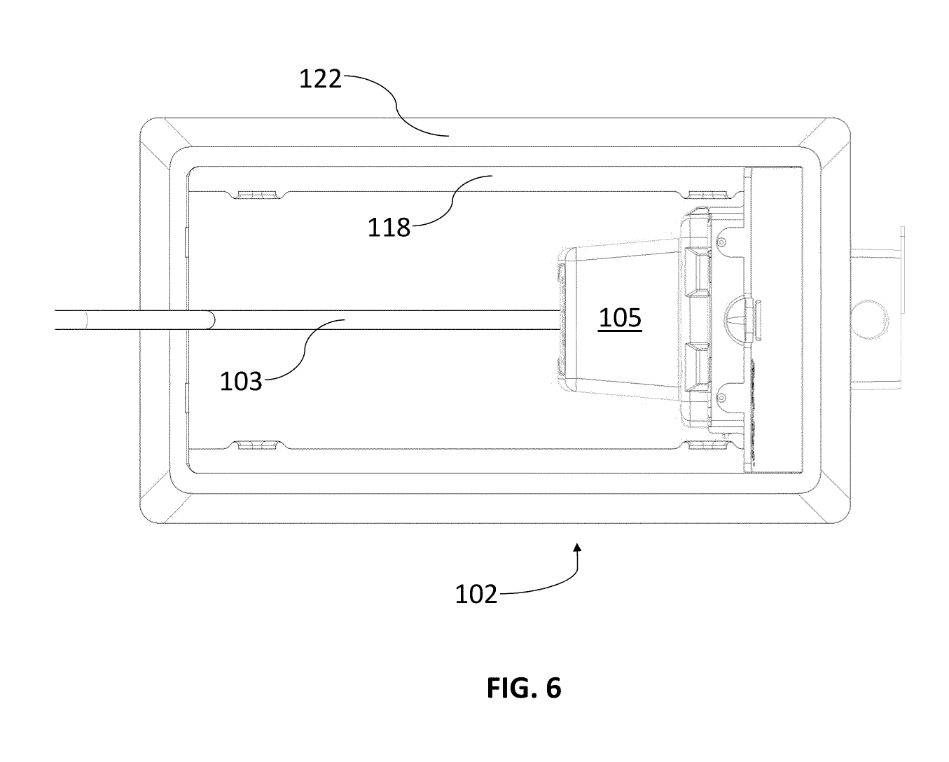

FIG. 3 shows an elevation view of the while-in-use floor cover 100 with the lid 104 in the open position. From this view, the electrical cord 103 is shown plugged in to the outlet which is housed inside the while-in-use box and cover 105 below the floor of the deck 101. Once plugged in to the outlet, the electrical cord 103 can be used to power an electrical device which is located above the floor of the deck 101. When the electrical cord is plugged in to the while-in-use box and cover 105 that is located under the flooring of the deck 101, the lid 104 of the while-in-use floor cover 100 may be shut so that there is not an exposed opening in the floor of the deck 101. To prevent the lid 104 from closing beyond a position which is horizontal and parallel with the flooring of the deck, the frame 102 comprises frame flanges 118, as shown in FIGS. 2 and 6, which protrude parallel to the inside of at least one side of the frame. With the lid 104 in the closed position, the electrical cord 103 is able to pass through a cut-out 106, which is more clearly shown in FIGS. 1-2 and FIG. 5, which is located along an edge 107 of the lid 104. FIG. 5, which shows a top plan view of the while-in-use floor cover 100 with the lid 104 in the closed position, clearly shows that the electrical cord 103 is able to pass through the lid 104 by way of the cut-out 106 which is located along an edge 107 of the lid.

Another feature of the present invention of the while-in-use floor cover which is shown in FIGS. 1-2 and FIG. 5 is the finger access aperture 108 which is accessible from the top surface 112 of the lid 104. The finger access aperture 108 allows an operator to open the lid 104 of the while-in-use floor cover 100 by inserting a finger and lifting the lid 104 so that an electrical cord 103 can be plugged in to or removed from an outlet which is housed by a while-in-use box and cover 105, as shown in FIG. 2, located underneath the surface of the deck 101.

FIGS. 1-3 show reinforcement walls 110 which are formed as an integral part of the lid 104 and which protrude from the bottom surface 114 of the lid 104. It is understood that these reinforcement walls 110 can be arranged in any type of configuration. The reinforcement walls 110 provide additional strength for the lid 104 of the while-in-use floor cover 100 when the lid 104 is in the closed position. This additional strength is needed due to the fact that individuals walking on the surface of the deck would subject the lid 104 to additional forces when standing on it or walking across it.

Lastly, another feature of the invention is shown in FIGS. 2-4. In FIGS. 2-4, it is shown that the frame surface walls 122 and the lid 104 of the while-in-use floor cover 100 are designed to be flush mounted with the deck 101 so as not to be a tripping hazard for individuals that are walking on the surface of the deck. The difference in elevation 123 between the surface of the deck 101 and the top surface of the lid 112 is minimal and only equals the thickness of the frame surface walls 122, as shown in FIG. 4. This minimal difference in elevation is small enough as to not be hazardous to individuals who are walking across the surface of the deck.

Although the invention has been described in detail above, it is expressly understood that it will be apparent to persons skilled in the relevant art that the invention may be modified without departing from the spirit of the invention. Various changes of form, design, or arrangement may be made to the invention without departing from the spirit and scope of the invention. Therefore, the above mentioned description is to be considered exemplary, rather than limiting, and the true scope of the invention is that defined in the following claims.

What is claimed is:

1. A weatherproof while-in-use floor cover for providing access to an adjacent while-in-use box which is mounted below an elevated floor having an opening, comprising:
a frame;
a lid which is hingedly attached to the frame;
at least one frame mounting wall which protrudes perpendicularly downward from at least one side of the frame;
at least one frame flange which protrudes parallel to the inside of at least one side of the frame;
wherein the frame and lid are mounted within the opening in the elevated floor such that the at least one frame mounting wall is affixed to the elevated floor to secure the frame and lid in position within the opening in the elevated floor;
wherein the lid can be opened or closed to allow access to the while-in-use box which is located below the elevated floor;
wherein the at least one frame flange prevents the lid from closing beyond a horizontal position which is parallel with the elevated floor; and
wherein the lid comprises a cut-out which is located along an edge of the lid such that the cut-out can receive an electrical cord to be plugged in to the while-in-use box which is located below the elevated floor when the lid of the while-in-use floor cover is in the closed position.

2. The weatherproof while-in-use floor cover of claim 1, wherein the elevated floor is a deck.

3. The weatherproof while-in-use floor cover of claim 1, wherein the lid comprises an aperture for inserting a finger such that the lid can be opened by a single finger operation.

4. The weatherproof while-in-use floor cover of claim 1, wherein the lid comprises multiple reinforcement walls which are located on the underside of the lid and that provide additional strength for the lid when force is applied to the top of the lid.

5. The weatherproof while-in-use floor cover of claim 1 wherein the frame and the lid are flush mounted with the elevated floor when the lid is in the closed position so as not to be a tripping hazard for individuals walking on the elevated floor.

6. The weatherproof while-in-use floor cover of claim 1 wherein the lid does not open beyond 90 degrees from horizontal such that it will close by force of gravity if left open by an operator.

7. The weatherproof while-in-use floor cover of claim 1 wherein the frame and lid are constructed from a weatherproof metal material.

8. The weatherproof while-in-use floor cover of claim 1 wherein the frame and lid are constructed from a weatherproof plastic material.

9. A weatherproof while-in-use floor cover for providing access to a detached while-in-use box which is mounted below an elevated floor having an opening, comprising:
a frame;
a lid which is hingedly attached to the frame;
at least one frame mounting wall which protrudes perpendicularly downward from at least one side of the frame;
at least one frame flange which protrudes parallel to the inside of at least one side of the frame;
wherein the frame and lid are mounted within the opening in the elevated floor such that the at least one frame mounting wall is affixed to the elevated floor to secure the frame and lid in position within the opening in the elevated floor;
wherein the lid can be opened or closed to allow access to the while-in-use box which is located below the elevated floor;
wherein the at least one frame flange prevents the lid from closing beyond a horizontal position which is parallel with the elevated floor;
wherein the lid comprises a cut-out which is located along an edge of the lid such that the cut-out can receive an electrical cord to be plugged in to the while-in-use box which is located below the elevated floor when the lid of the while-in-use floor cover is in the closed position; and
wherein the lid comprises an aperture for inserting a finger such that the lid can be opened by a single finger operation.

10. The weatherproof while-in-use floor cover of claim 9, wherein the elevated floor is a deck.

11. The weatherproof while-in-use floor cover of claim 9, wherein the lid comprises multiple reinforcement walls which are located on the underside of the lid and that provide additional strength for the lid when force is applied to the top of the lid.

12. The weatherproof while-in-use floor cover of claim 9 wherein the frame and the lid are flush mounted with the elevated floor when the lid is in the closed position so as not to be a tripping hazard for individuals walking on the elevated floor.

13. The weatherproof while-in-use floor cover of claim 9 wherein the lid does not open beyond 90 degrees from horizontal such that it will close by force of gravity if left open by an operator.

14. The weatherproof while-in-use floor cover of claim 9 wherein the frame and lid are constructed from a weatherproof metal material.

15. The weatherproof while-in-use floor cover of claim 9 wherein the frame and lid are constructed from a weatherproof plastic material.

16. A weatherproof while-in-use floor cover for providing access to a detached while-in-use box which is mounted below an elevated floor having an opening, comprising:
a frame;
a lid which is hingedly attached to the frame;
at least one frame mounting wall which protrudes perpendicularly downward from at least one side of the frame;
at least one frame flange which protrudes parallel to the inside of at least one side of the frame;
wherein the frame and lid are mounted within the opening in the elevated floor such that the at least one frame mounting wall is affixed to the elevated floor to secure the frame and lid in position within the opening in the elevated floor;
wherein the lid can be opened or closed to allow access to the while-in-use box which is located below the elevated floor;
wherein the at least one frame flange prevents the lid from closing beyond a horizontal position which is parallel with the elevated floor;
wherein the lid comprises a cut-out which is located along an edge of the lid such that the cut-out can receive an electrical cord to be plugged in to the while-in-use box which is located below the elevated floor when the lid of the while-in-use floor cover is in the closed position;
wherein the lid comprises an aperture for inserting a finger such that the lid can be opened by a single finger operation; and
wherein the lid does not open beyond 90 degrees from horizontal such that it will close by force of gravity if left open by an operator.

17. The weatherproof while-in-use floor cover of claim 16, wherein the lid comprises multiple reinforcement walls which are located on the underside of the lid and that provide additional strength for the lid when force is applied to the top of the lid.

18. The weatherproof while-in-use floor cover of claim 16 wherein the frame and the lid are flush mounted with the elevated floor when the lid is in the closed position so as not to be a tripping hazard for individuals walking on the elevated floor.

19. The weatherproof while-in-use floor cover of claim 16 wherein the frame and lid are constructed from a weatherproof metal material.

20. The weatherproof while-in-use floor cover of claim 16 wherein the frame and lid are constructed from a weatherproof plastic material.
